(19) United States
(12) Patent Application Publication
(10) Pub. No.: US 2006/0224337 A1
(43) Pub. Date: Oct. 5, 2006

(54) Programmable current load systems and methods

(75) Inventors: Peter Hazucha, Beaverton, OR (US); Gerhard Schrom, Hillsboro, OR (US); Tanay Karnik, Portland, OR (US)

Correspondence Address: JUNG-HUA KUO;C/O PORTFOLIOIP, P. O. BOX 52050, MINNEAPOLIS, MN, 55402, US

(73) Assignee: Intel Corporation, A DELAWARE CORPORATION, Santa Clara, CA (US)

(21) Appl. No.: 11/095,950

(22) Filed: Mar. 31, 2005

(51) Int. Cl. G01R 19/00

(52) U.S. Cl. 702/64

(57) ABSTRACT

One disclosed system includes a plurality of current sink elements coupled between a power supply and a reference potential. A plurality of multiplexers are configured to enable the current sink elements to sink current, and a plurality of selection inputs are configured to control the state of the multiplexers.

### BACKGROUND

As microprocessors and other integrated circuits become denser and faster and rely on lower operating voltages (e.g., less than 1.5 volts), increased demands are placed on these circuits' power distribution systems. For example, higher switching speeds and clock frequencies lead to increased current demands and to higher inductive noise on the power distribution grid. Similarly, power saving modes of operation can lead to large and rapid swings in current demand. Many circuits also impose relatively strict restrictions on the on-die voltage variation (e.g., less than 10%, peak-to-peak), and motherboard voltage regulator modules (VRM), decoupling capacitors, and other mechanisms are becoming increasingly inadequate at meeting these requirements. These issues have pushed designers to explore new on-die voltage regulation and power distribution techniques.

### BRIEF DESCRIPTION OF THE DRAWINGS

Reference will be made to the following drawings, in which:

FIG. 1 is an illustration of a time-varying current sink for use in producing a variety of load current waveforms.

FIG. 2 is an illustration of a test-current waveform.

FIG. 3 is an illustration of a test-current waveform produced by time-staggered current sinks.

FIG. 4 is an illustrative embodiment of a programmable current load.

FIGS. 5A-5E are illustrations of how the system shown in FIG. 4 can be used to produce different current waveforms by setting the selection inputs.

FIG. 6 is an illustration of a programmable current sink/switch that can be used with the system shown in FIG. 4.

FIG. 7 is an illustration of another embodiment of a programmable current sink/switch that can be used with a system such as that shown in FIG. 4.

FIG. 8 is an illustration of a dual-sloped test current waveform.

FIGS. 9A-9C illustrate ways of using a programmable current load such as that shown in FIG. 4 to simulate various current loads.

FIG. 10 illustrates current waveforms that correspond to various settings of the selection inputs of a programmable current load such as that shown in FIG. 4.

FIG. 11 is an illustration of a method of testing a power supply using a current load such as that shown in FIG. 4.

### DESCRIPTION OF SPECIFIC EMBODIMENTS

Systems and methods are disclosed for providing a programmable current load. It should be appreciated that these systems and methods can be implemented in numerous ways, several examples of which are described below. The following description is presented to enable any person skilled in the art to make and use the inventive body of work. The general principles defined herein may be applied to other embodiments and applications. Descriptions of specific embodiments and applications are thus provided only as examples, and various modifications will be readily apparent to those skilled in the art. For example, although several examples are provided in the context of on-chip testing of power supplies, it will be appreciated that the same principles can be readily applied in other contexts as well. Accordingly, the following description is to be accorded the widest scope, encompassing numerous alternatives, modifications, and equivalents. For purposes of clarity, technical material that is known in the art has not been described in detail so as not to unnecessarily obscure the inventive body of work.

Techniques are described for testing on-die voltage regulation, power distribution, and noise reduction designs, thereby enabling circuit designers to evaluate designs prior to production of a completed integrated circuit. Time varying loads can be provided to mimic expected current demands, and can be distributed along the on-die power distribution grid. The loads may be used to design and evaluate power distribution systems, to model load requirements, and/or to test power noise suppression techniques before time consuming and costly incorporation into an integrated circuit.

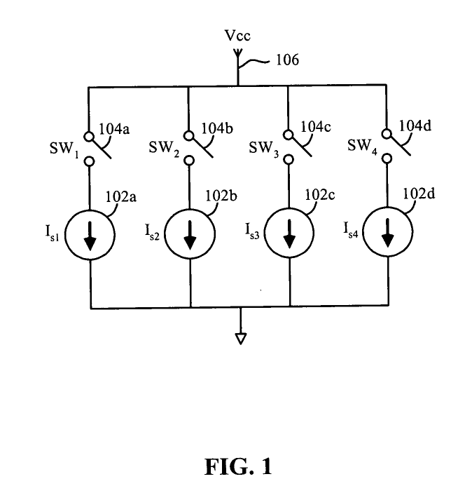

Time varying loads can be used to test proposed power distribution grids, ground grids, noise suppression techniques, and/or voltage regulation circuitry by mimicking transient power demands. As shown in FIG. 1, a number of current sinks 102 can be coupled (e.g., connected, as shown) to a power supply 106 for testing. The number of current sinks 102 can vary depending on the application, and the aggregation of the current sinks 102 can be chosen to model the aggregate current demands of the circuit that will ultimately be coupled to the power supply 106 under test.

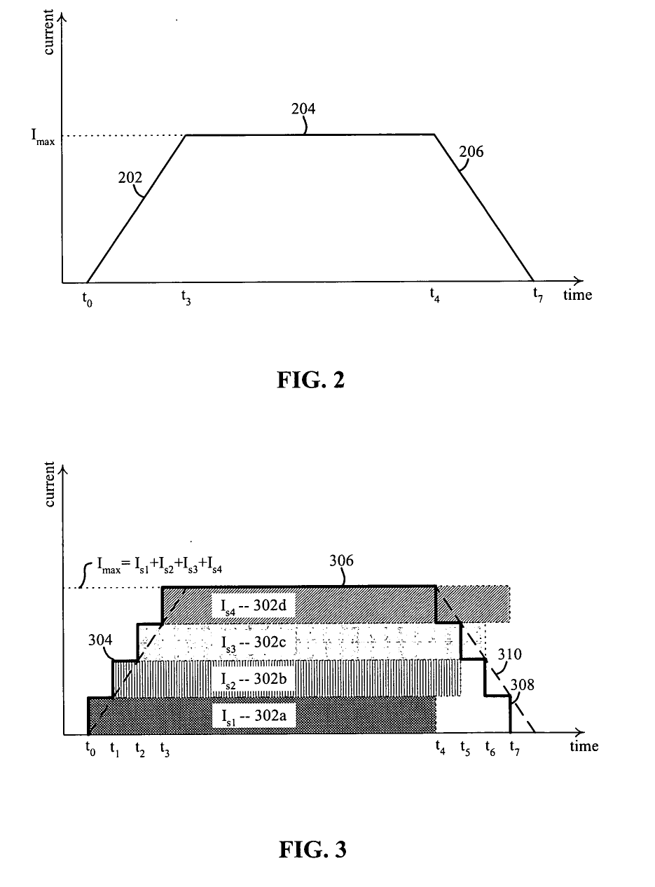

In the example shown in FIG. 1, four current sinks, Iₛ₁-Iₛ₄, 102a-102d are coupled to power supply 106 using switches, SW₁-SW₄, 104a-104d to create a time-varying load. The load presented to the power supply 106 will vary depending on the number of current sinks 102 (sometimes also referred to as “current sources”) that are coupled to the power supply 106, and on their respective values. For example, the current sinks shown in FIG. 1 could be used to model the test waveform illustrated in FIG. 2, or other waveforms.

FIG. 2 shows an illustrative test current waveform. As shown in FIG. 2, the test current waveform includes a leading edge 202, an “on” period 204, and a trailing edge 206. The current rises from zero to Iₘₐₓ from time t₀ to t₃, remains at Iₘₐₓ from time t₃ to t₄, and declines from Iₘₐₓ to zero from time t₄ to t₇. The waveform shown in FIG. 2 could, for example, represent the current drawn by an integrated circuit to which a power supply is to be coupled.

Embodiments of the time varying loads described herein can be used to mimic the waveform shown in FIG. 2, as well as many other waveforms, and thereby enable testing of a power supply's response to a current load without the necessity of coupling the power supply to the integrated circuit that will ultimately produce the current load.

One way to generate a test current waveform such as that shown in FIG. 2 is to turn on a group of current sinks such as those shown in FIG. 1 in a staggered fashion, such that the current response waveform of each current sink is additively combined with that of each of the other current sinks in the group.

FIG. 3 illustrates how the circuit shown in FIG. 1 could be used to approximate the waveform shown in FIG. 2. FIG. 3 shows four, time-staggered vertically stacked, rectangular areas 302a, 302b, 302c, 302d, representing the current drawn by each current sink, Iₛ₁-Iₛ₄, respectively, from the power supply that is being tested. The total load current, which is the sum of the currents drawn by each sink element, is shown in bold, with the leading edge 304, peak 306, and trailing edge 308 labeled in FIG. 3.

As shown in FIG. 3, just prior to time t₀, the switches SW₁-SW₄ are open, and the load current is zero. At time t₀, switch SW₁ is closed, raising the load current by Iₛ₁. At time t₁, switch SW₂ is closed, raising the load current by Iₛ₂. Similarly, switches SW₃ and SW₄ are closed in succession at times t₂ and t₃, respectively, to incrementally raise the load current as shown in FIG. 3. Between times t₃ and t₄, all switches SW₁-SW₄ remain closed to produce the peak load current 306. At time t₄, switch SW, is opened, thereby uncoupling sink element Iₛ₁ and reducing the load current by Iₛ₁. At time t₅, switch SW₂ is opened, uncoupling sink element Iₛ₂ and reducing the load current by Iₛ₂. Similarly, switches SW₃ and SW₄ are opened in succession at times t₆ and t₇, respectively, to incrementally lower the load current as shown by the trailing edge 308 of the current waveform shown in FIG. 3.

As seen in FIG. 3, the load current produced by the staggered sink elements may closely approximate the test current waveform of FIG. 2, shown as a dashed line 310 in FIG. 3. In some embodiments, the sink elements may be turned on and off gradually to produce a smooth ramp more closely approximating the dashed line.

It should be appreciated that FIGS. 1 and 3 are provided for purposes of illustration, and not limitation, and that a number of modifications could be made without departing from the principles that are illustrated therein. For example, although four current sink elements are shown in FIG. 3, it should be appreciated that any number could be used to increase (or decrease) the resolution of the test-current waveform. Similarly, it should be appreciated that the magnitudes and the timing of the currents may be scaled to provide different rise and fall transition characteristics. For example, in some embodiments each switch, SW₁-SW₄, can be held closed for the same fixed period of time (e.g., periods t₀-t₄, t₁-t₅, t₂-t₆, t₃-t₇ could be equal). In such embodiments, the trailing edge of the current waveform will typically be an inversion of the leading edge. It should also be appreciated that while the test current waveforms have been shown as rising from zero, with certain technologies (e.g., scaled complementary metal oxide semiconductor (CMOS)) there may be a small amount of leakage current (e.g., 1 microampere per micrometer width) even when switches (e.g., transistors) are in an off state. This leakage current will typically be much less than the magnitude of the test current waveform, and can be ignored.

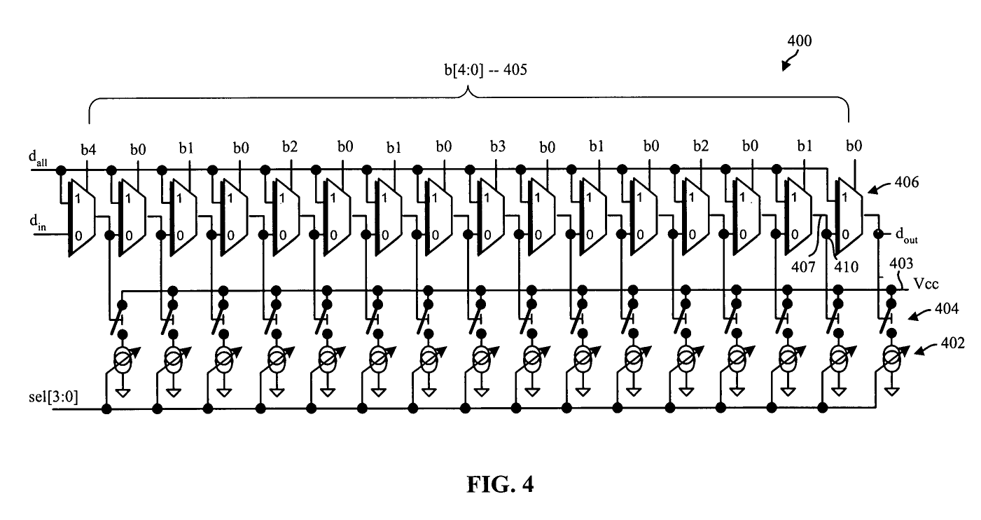

FIG. 4 is a more detailed illustration of an embodiment of a programmable current load 400. Current sinks 402 are selectively coupled to the power supply under test, Vcc, 403 by the enable inputs of switches 404. The outputs 407 of multiplexers 406 control the enable inputs of switches 404, and thus the multiplexers effectively control the current response of the programmable current load 400.

In the embodiment shown in FIG. 4, the multiplexers 406 are coupled in series, with the output 407 of each multiplexer coupled to one of the inputs 410 of the next multiplexer in the series. Each multiplexer 406 is used to select which of its two inputs will appear on its output 407, and is also used to introduce a fixed delay in the path of the signal propagating from the selected input to the output 407. The state of each multiplexer 406 is controlled by a selection input 405 (i.e., b0-b4).

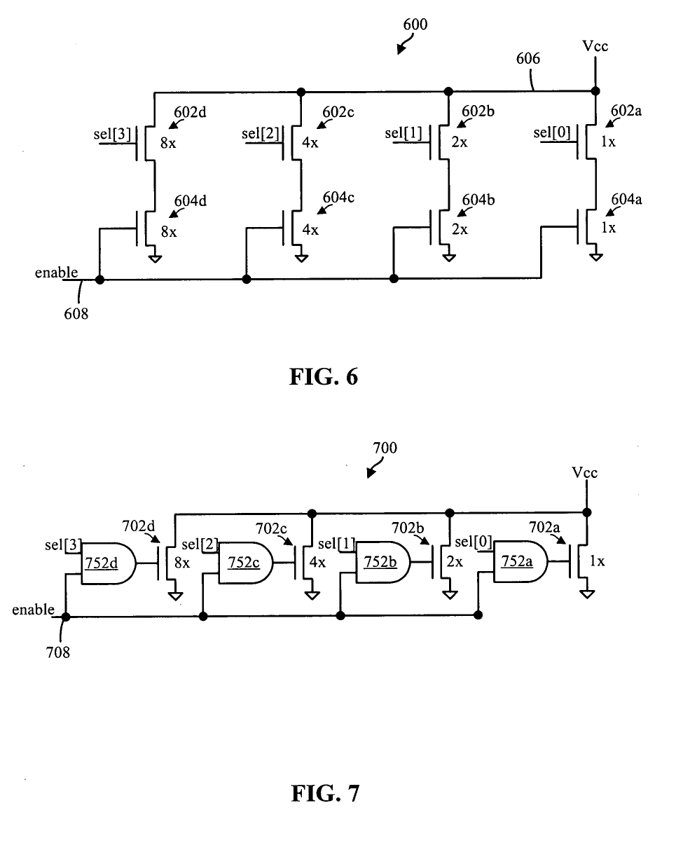

In the embodiment shown in FIG. 4, the programmable current load 400 includes sixteen multiplexers 406 controlled by five selection inputs 405: b4, b3, b2, b1, and b0 (referred to collectively as b[4:0]). The outputs 407 of the multiplexers 406 are used to enable or disable current produced by programmable current sink elements 402. As explained in more detail in connection with FIGS. 6 and 7, each current sink 402 is capable of producing a pulse of current with an amplitude determined by the selection inputs sel[3:0].

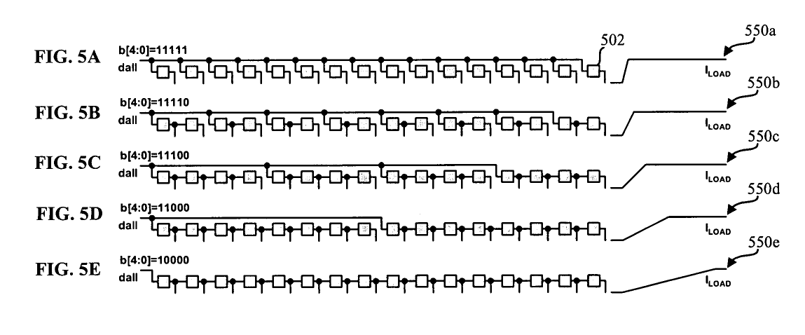

When an input signal is applied to programmable current load 400 via dₐₗₗ or dᵢₙ, the signal propagates to current enable inputs 404 through multiplexers 406. The delay between the input signal and the current waveform seen by power supply 403 is determined by the time it takes a signal to propagate from either dₐₗₗ or dᵢₙ to the enable inputs 404 of the current sink elements 402. This delay is, in turn, determined by the number of multiplexers coupled in series. That is, the delay is directly related to the number of multiplexers through which the input signal must travel before reaching the enable inputs 404 of the current sinks 402. By programming the selection inputs b[4:0], the ramp time of the current waveform can be controlled, as illustrated in FIGS. 5A-5E. In one embodiment, the rise time of the current sink elements is roughly matched to the multiplexer delays, so that the overall current waveform is relatively smooth.

FIGS. 5A-5E illustrate various output current waveforms 550a-550e that can be selected using various combinations of selection inputs b[4:0]. FIGS. 5A-5E also show, for each waveform, the signal path delay from dₐₗₗ to the enable input 404 of each of the current sink elements 402 in FIG. 4. Each grey box 502 represents the delay associated with a signal passing through one multiplexer in FIG. 4.

As shown in FIG. 5A, if b[4:0]=11111, all of the multiplexers 406 in FIG. 4 couple dₐₗₗ directly to their outputs 407. Thus, upon receiving a trigger pulse on dₐₗₗ, all of the current sink elements 402 will turn on substantially simultaneously and produce a single large step in load current, as shown by current waveform 550a.

As shown in FIG. 5B, a longer ramp can be produced by setting bit b0 to 0, and setting b[4:1] to 1111. This results in half of the current elements turning on after a single multiplexer delay, and the other half turning on after two multiplexer delays, since half of the multiplexers will couple the input trigger pulse dₐₗₗ directly to their corresponding current sink's enable switch, while the remainder of the multiplexers only receive the trigger pulse once it has passed through the preceding multiplexer in the series. Load current waveform 550b illustrates the current ramp for this setting of the selection inputs b[4:0].

Similarly, even longer ramp times can be achieved by setting the selection inputs b[4:0] to 11100, as shown in FIG. 5C, or to 11000, as shown in FIG. 5D. The longest ramp time is obtained by coupling all of the multiplexers in series, corresponding to b[4:0]=10000, as shown in FIG. 5E. Here, the input pulse must propagate through all of the multiplexers in the series before enabling the final current sink in the series.

The individual current sinks 402 and enable switches 404 shown in FIG. 4 can be implemented in a variety of ways. Two illustrative embodiments are shown in FIGS. 6 and 7. The current sink elements shown in FIGS. 6 and 7 produce current at the drain terminal of a transistor (e.g., a metal-oxide semiconductor field effect transistor (MOSFET)). By employing several transistors with binary weighted currents in parallel, the amplitude of the total current drawn by the current element can be digitally programmed.

Referring to FIG. 6, a current sink/switch element 600 is shown that includes eight n-type metal oxide semiconductor (NMOS) transistors 602a, 602b, 602c, 602d, 604a, 604b, 604c, 604d, scaled geometrically in powers of two to sink I, 2I, 4I, and 8I units of current, respectively, where a current unit, I, is the amount of current drawn by transistor 602a (e.g., 2.5 milliamps, or any other suitable value). The current sink/switch element 600 may be programmed to sink any integer multiple of current, I, up to a maximum of 15 times the current drawn by transistor 602a (i.e., (2⁴−1)I, where 4 is the number of selection inputs). The drains of transistors 602a-602d are coupled to Vcc 606, where the transistor sink currents are summed.

Selection inputs sel[3:0] are used to selectively turn on transistors 602a-602d to produce any desired load current from 0 to 15 current units. For example, if sel[3:0] is set to 1010, transistors 602b and 602d will be turned on, while transistors 602a and 602c will be turned off, and the total current drawn from power supply Vcc will be 2+8=10 current units. Enable input 608 plays the role of switch 404 in FIG. 4. A low voltage on enable input 608 turns transistors 604a-604d off, and can thus be used to turn off the entire current sink/switch element 600 by blocking the flow of current from Vcc to a reference potential (e.g., ground), regardless of the value of selection inputs sel[3:0].

FIG. 7 shows another embodiment of a programmable current sink/switch combination 700. Similar to FIG. 6, the programmable current sink/switch 700 shown in FIG. 7 includes four transistors 702a, 702b, 702c, 702d scaled geometrically in powers of two to sink I, 2I, 4I, and 8I units of current, respectively. In the embodiment shown in FIG. 7, the gate of each transistor 702a-702d is driven by a respective AND gate 752a-752d (or, equivalently, a NAND gate followed by an inverter driver). The AND gates each may have one input driven by a common enable control line 708 and a second input driven by one of selection inputs sel[3:0].

The selection inputs sel[3:0] can be supplied to the current sink elements in any suitable manner. For example, the desired combination of selection inputs could be serially shifted into a series of flip-flops, the outputs of which would drive the selection inputs shown in FIGS. 6 and 7, as described in commonly assigned U.S. patent application Ser. No. 10/097136, Publication No. 20030176982 A1, entitled “Manufacturing integrated circuits and testing on-die power supplies using distributed programmable digital current sinks.” A similar approach could also be used to program the selection inputs b[4:0] in FIG. 4.

It should be appreciated that FIGS. 4-7 are provided for purposes of illustration, and not limitation, and that a number of variations can be made to the systems and methods described in connection therewith. For example, it should be appreciated that the current sinks 402 and switches 404 shown in FIG. 4 can be implemented in any suitable manner, and that a number of modifications could be made to the illustrative implementations shown in FIGS. 6 and 7. For example, while FIGS. 6 and 7 show the use of four selection input bits and corresponding transistors, it will be appreciated that any suitable number of selection inputs and transistors could be used to provide more or less granular control of the current drawn from the power supply, in order to provide a current resolution and range suitable to the application at hand. For example, additional scaled transistors and selection inputs could be provided to enable the selection of currents of 31I, 63I, or the like.

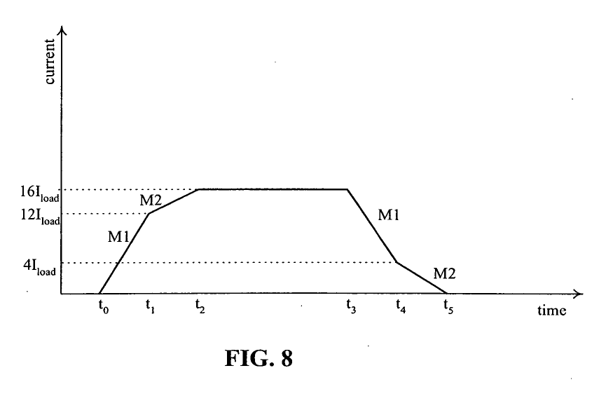

Similarly, while FIGS. 5A-5E show a variety of linear current ramps, it should be appreciated that a programmable current load such as that shown in FIG. 4 can also be used to produce non-linear current ramps by applying different values to b[4:0]. For example, without limitation, the programmable current load shown in FIG. 4 could also be used to produce a waveform with dual-sloped leading and trailing edges, such as that shown in FIG. 8. In the example waveform shown in FIG. 8, the current rises to 12I_{load} with a slope of M₁ from t₀ to t₁, and rises with a slope of M₂ from time t₁ to t₂, reaching a final value of 16I_{load}, where I_{load} is the load current produced by a single current sink element 402 in the programmable current load shown in FIG. 4. As shown in FIG. 8, the current declines from 16I_{load} to 4I_{load} with a slope of −M₁ from time t₃ to t₄, and then continues to decline from 4I_{load} to zero with a slope of −M₂ from time t₄ to t₅.

The waveform shown in FIG. 8 can be produced by the programmable current load shown in FIG. 4 by, for example, programming the delay selection inputs b[4:0] and/or the current selection inputs sel[3:0]. For example, a load current of the general form shown in FIG. 8 could be obtained by setting the selection inputs b[4:0] to 11101, thus causing the load current to rise initially after one multiplexer delay from 0 to 12 current units, I_{load}, and then rise from 12I_{load} to 16I_{load} after another multiplexer delay. Alternatively, in some embodiments one or more of the current sinks 402 in FIG. 4 could be individually programmed (e.g., by providing them with their own dedicated selection inputs sel[3:0]). In such an embodiment, a waveform such as that shown in FIG. 8 could be obtained by, e.g., setting b[4:0] to 11100, while setting the current selection inputs, sel[3:0], of the current sinks corresponding to the b1 inputs to a lower value than the current selection inputs for the other current sinks (e.g., by setting sel[3:0] to 0111 for the current sinks coupled to multiplexers selected by the b1 input, while setting sel[3:0] to 1111 for the other current sinks).

Moreover, although variations in current turn on times (e.g., t₀-t₁≠t₁-t₂) are not provided for by the illustrative embodiment shown in FIG. 4, if desired, such variations could be obtained by, e.g., adding one or more variable (e.g., selectable) delay elements between multiplexers 406 and current sinks/switches 402/404. Providing a variable on time for each current sink can increase the versatility of the current load 400 by enabling it to produce more complex test-current waveforms at the cost of increased circuit size and complexity.

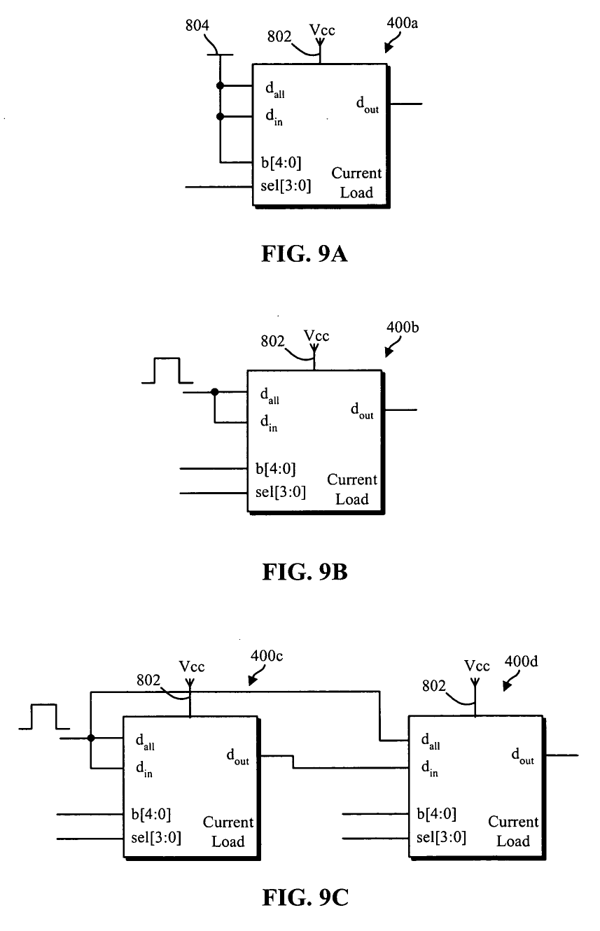

FIGS. 9A-9C show a programmable current load, such as that shown in FIG. 4, being used in various scenarios. In particular, FIG. 9A shows how a current load 400a, such as that shown in FIG. 4, can be used to produce a DC load current. In the example shown in FIG. 9A, the inputs dₐₗₗ, dᵢₙ, and b[4:0] are all set to a high voltage level, and the current selection inputs sel[3:0] are set to draw any suitable value of current, I. The result is a load current that ramps quickly from zero to I after only a single multiplexer delay, as shown in FIG. 5A. The current will remain at I until dₐₗₗ and dᵢₙ are brought back to a low voltage. Note that in the example shown in FIG. 9A, dₐₗₗ, dᵢₙ, and b[4:0], are coupled to a power supply 804 other than the power supply under test 802.

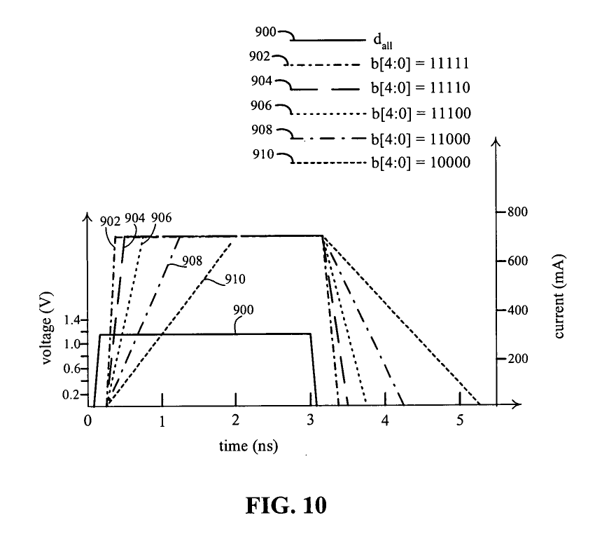

FIG. 9B shows how a programmable current load 400b such as that shown in FIG. 4 can be used to produce a pulse with programmable rise and fall times (i.e., ramp times). As shown in FIG. 9B, a pulse supplied by, e.g., an external pulse generator is fed to the dₐₗₗ and dᵢₙ inputs of programmable load 400b. The selection inputs b[4:0] are used to select the amount of delay experienced by the input pulse before it reaches the enable inputs of current sinks 402. Several illustrative load waveforms that could be produced by a programmable current load configured in this manner are described below in connection with FIG. 10.

FIG. 9C shows how current loads 400c, 400d can be coupled in series to produce an output waveform having up to twice the maximum ramp time and up to twice the maximum amplitude of a single current load. As shown in FIG. 9C, the output, dₒᵤₜ, of one programmable current load 400c is coupled to the dᵢₙ input of another programmable current load 400d. In some embodiments, programmable current loads 400c and 400d can share selection inputs b[4:0], thus enabling production of current ramps of up to twice the amplitude as could be produced by a single programmable current load 400. In other embodiments, each programmable current load 400c, 400d has its own dedicated set of selection inputs, thereby enabling production of current waveforms having up to twice the ramp length and twice the amplitude of a single programmable current load 400.

FIG. 10 shows examples of load current waveforms produced by a programmable current load such as that shown in FIGS. 4 and 9B. The current amplitude setting has been kept constant by setting sel[3:0] to a constant value, and the ramp time has been varied by varying b[4:0]. Rising or falling current ramps can be triggered by applying high or low voltages, respectively, on external voltage trigger signal dₐₗₗ 900. As shown in FIG. 10, waveform 902 would result from setting b[4:0] to 11111. Similarly, successively longer ramp times can be selected using the b[4:0] inputs, as illustrated by waveforms 904, 906, 908, and 910.

A network of programmable current loads such as those shown in FIGS. 4 and 9A-9C can be distributed along a power distribution grid under test. The number of current loads may vary depending on the application, and it will be appreciated that any suitable number or distribution of current loads can be used. For example, a smaller number of current loads could be used to test relatively small integrated circuits, while a larger number could be used to test larger integrated circuits such as microprocessors. Some of the current loads can be coupled in series as shown in FIG. 9C, while others can be independently coupled to different parts of the power supply under test. More accurate modeling and testing of an on-die power distribution grid may be achieved by distributing the time-varying loads along the grid according to planned circuit requirements. The aggregation of the distributed loads may be chosen to model the aggregate current demands of the circuit.

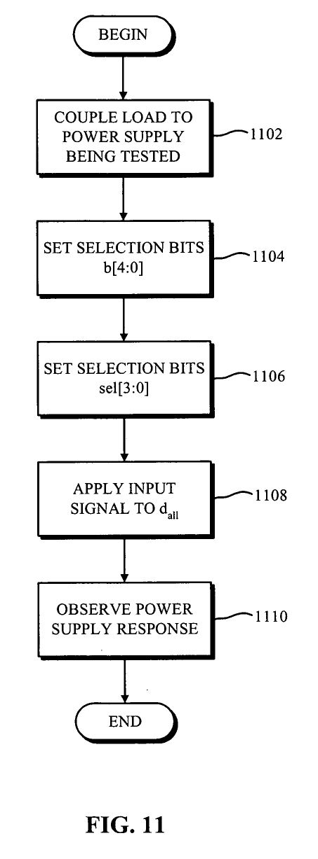

FIG. 11 is an illustration of a method for testing a power supply using a current load such as that shown in FIG. 4. Referring to FIG. 11, a current load such as that shown in FIG. 4 is coupled to a power supply that is to be tested (block 1102). The selection inputs b[4:0] and sel[3:0] are then set to enable production of a load current waveform with the desired ramp length and amplitude (blocks 1104 and 1106). An input signal is then applied to the dₐₗₗ input of the current load (block 1108), causing the current load to begin drawing current from the power supply in accordance with the waveform selected. The performance of the power supply can then be observed (block 1110), and the power supply's design (and/or the design of the circuit that is to be attached to the power supply) can be modified if necessary.

Thus, embodiments of the systems and methods described herein can be used for a wide variety of purposes and in a wide variety of applications. For example, embodiments of the programmable current loads described herein can be used to facilitate the design of cost-effective and reliable power delivery systems by simulating the high frequency transient characteristics of a microprocessor load, and facilitating the selection of decoupling capacitors and the like. In addition, embodiments of the systems and methods described herein can be used for testing and characterization of on-die power converters and voltage regulators, and/or for measuring package resonance, alternating current (AC) and direct current (DC) droop, on-die voltage regulator impedance, and the like.

Thus, while several embodiments are described and illustrated herein, it will be appreciated that they are merely illustrative. For example, without limitation, while various embodiments of a power distribution grid and test circuitry have been shown in the context of silicon implementations, it will be appreciated that the power distribution grid and/or the test circuitry could be modeled in a computer simulation system as well. Accordingly, other embodiments are within the scope of the following claims.

What is claimed is:

1. A system comprising:
a plurality of current sink elements operable to be coupled between a power supply and a reference potential;
a plurality of multiplexers configured to enable the current sink elements to sink current; and
a plurality of selection inputs configured to control the state of the multiplexers.

2. The system of claim 1, in which at least one of the plurality of current sink elements comprises:
a plurality of transistors, each scaled to sink a respective current when on; and
a plurality of current selection inputs, each current selection input operatively coupled to a gate of a corresponding one of the transistors, and each current selection input being operable to turn its corresponding transistor on.

3. The system of claim 2, in which the at least one of the plurality of current sink elements further comprises:
an enable input, the enable input being coupled to an output of one of the plurality of multiplexers, and being operable to prevent the current sink element from sinking current.

4. The system of claim 2, in which a first of the plurality of transistors is scaled to sink a predetermined amount of current when on, and in which each successive one of the plurality of transistors is scaled to sink approximately twice the amount of current as a previous one of the plurality of transistors.

5. The system of claim 1, in which at least one of the plurality of multiplexers is configured to accept an external input signal, and, based on one of the selection inputs, to either (a) pass the external input signal to an enable input of a current sink element, or (b) pass the output of another of the plurality of mutiplexers to the enable input of the current sink element.

6. The system of claim 1, in which each multiplexer comprises two multiplexer inputs and a multiplexer output, and in which one of the selection inputs is operable to select which of the two multiplexer inputs appears on the multiplexer output.

7. The system of claim 6, in which the plurality of multiplexers are coupled in series, with the output of at least one of the plurality of multiplexers coupled to (a) one of the two inputs of a next multiplexer in the series, and (b) an enable input of one of the current sink elements.

8. The system of claim 1, further comprising:
an input signal generator configured to supply a voltage pulse on an input of each of the multiplexers.

9. The system of claim 8, in which each multiplexer comprises two multiplexer inputs and a multiplexer output, and in which a first of the two multiplexer inputs is coupled to the input signal generator, and in which a second of the two multiplexer inputs is coupled to one of: a multiplexer output of one of the plurality of multiplexers, an input from a second system, or the input signal generator.

10. The system of claim 9, in which the second system comprises a programmable current load.

11. The system of claim 1, in which the selection inputs are effectively operable to select between different ramp characteristics of a test current waveform formed by summing the currents flowing through the plurality of current sink elements.

12. The system of claim 1, in which the selection inputs are effectively operable to select between a number of test current waveforms having substantially linear ramp up characteristics, the number being equal to the number of selection inputs, and in which the substantially linear current ramps range in length from one multiplexer delay unit to 2^{N-1} multiplexer delay units, where N is the number of selection inputs.

13. The system of claim 1, in which each of the multiplexers is substantially the same size, and introduces substantially the same propagation delay between its inputs and its output.

14. The system of claim 1, further comprising:
a second plurality of current sink elements operable to be coupled between the power supply and a reference potential; and
a second plurality of multiplexers configured to enable the second plurality of current sink elements to sink current; wherein
the plurality of selection inputs is configured to control the state of the second plurality of multiplexers, and wherein an input of a first of said second plurality of multiplexers is coupled to an output of a multiplexer in the plurality of multiplexers.

15. The system of claim 1, further comprising one or more variable delay elements coupled between an output of at least one of the plurality of multiplexers and a corresponding current sink element.

16. A method comprising:
coupling a power supply to a programmable current load, the programmable current load having a plurality of current sink elements operable to draw current from the power supply;
applying a set of selection inputs to the programmable current load, the set of selection inputs being operable to select a length of delay associated with turning on each of the plurality of current sink elements; and
applying an input waveform to the programmable current load, the input waveform being operable to turn on the plurality of current sink elements after propagating through a plurality of delay elements, as determined by the set of selection inputs.

17. The method of claim 16, further comprising:
applying second and third sets of selection inputs to the programmable current load, the second set of selection inputs being operable to select a magnitude of current drawn by one or more of the plurality of current sink elements, and the third set of selection inputs being operable to select a magnitude of current drawn by a different one or more of the plurality of current sink elements.

18. The method of claim 16, further comprising:
applying a second set of selection inputs to the programmable current load, the second set of selection inputs being operable to select a magnitude of current drawn by each of the plurality of current sink elements.

19. The method of claim 18, in which the sets of selection inputs are chosen such that the programmable current load generates a load current that mimics the load current drawn by a predetermined circuit.

20. The method of claim 19, further comprising:
observing the power supply's response to the load current, and
reconfiguring the power supply and/or the predetermined circuit based on the observations.

21. A system comprising:
a power distribution grid;
an input pulse generator; and
a network of programmable load elements coupled between the power distribution grid and a reference potential, at least one of the network of programmable load elements comprising:
a plurality of current sink elements coupled between the power distribution grid and the reference potential;
a plurality of multiplexers configured to enable the current sink elements to sink current; and
a plurality of selection inputs configured to control the state of the multiplexers;
wherein at least one of the plurality of multiplexers is configured to accept an external input signal from the input pulse generator, and, based on one of the selection inputs, to either (a) directly pass the external input signal to an enable input of a current sink element, or (b) pass the output of another one of the plurality of multiplexers to the enable input of the current sink element.

22. The system of claim 21, in which at least one of the plurality of current sink elements comprises:
a plurality of transistors, each transistor being scaled to sink a respective current when on; and
a plurality of current selection inputs, each current selection input operatively coupled to a gate of a corresponding one of the transistors, and each current selection input being operable to turn its corresponding transistor on.

23. The system of claim 21, in which the plurality of selection inputs are operable to select a load current waveform for generation by the current sink elements.
